(19) United States
(12) Patent Application Publication
(10) Pub. No.: US 2026/0304984 A1
(43) Pub. Date: Oct. 1, 2026

(54) IMAGING DEVICE AND ELECTRONIC APPARATUS

(71) Applicant: SONY SEMICONDUCTOR SOLUTIONS CORPORATION, Kanagawa (JP)

(72) Inventor: Kenya NISHIO, Kanagawa (JP)

(21) Appl. No.: 19/478,053

(22) PCT Filed: Apr. 17, 2024
(86) PCT No.: PCT/JP2024/015207

§ 371 Date: Oct. 23, 2025

(30) Foreign Application Priority Data
Apr. 28, 2023 (JP) 2023-074722

(51) Int. Cl. H10F 39/00

(52) U.S. Cl. CPC H10F 39/806; H10F 39/811

(57) ABSTRACT

An imaging device according to one embodiment of the present disclosure includes a first photoelectric conversion element, a light guide member, and a second photoelectric conversion element. The first photoelectric conversion element photoelectrically converts light. The light guide member includes a plurality of first structures. Infrared light transmitted through the first photoelectric conversion element enters the light guide member. The second photoelectric conversion element photoelectrically converts the infrared light that enters through the light guide member.

### TECHNICAL FIELD

The present disclosure relates to an imaging device and an electronic apparatus.

### BACKGROUND ART

An imaging device has been proposed that includes a photodiode layer that photoelectrically converts a wavelength region component of visible light, and a photodiode layer that photoelectrically converts a wavelength region component of near-infrared light (PTL 1).

### CITATION LIST

### Patent Literature

PTL 1: Japanese Unexamined Patent Application Publication No. 2013-70030

### SUMMARY OF INVENTION

What is desired of an imaging device is to efficiently receive incident light.

It is desirable to provide an imaging device that is configured to efficiently receive light.

An imaging device according to one embodiment of the present disclosure includes a first photoelectric conversion element, a light guide member, and a second photoelectric conversion element. The first photoelectric conversion element photoelectrically converts light. The light guide member includes a plurality of first structures. Infrared light transmitted through the first photoelectric conversion element enters the light guide member. The second photoelectric conversion element photoelectrically converts the infrared light that enters through the light guide member.

An imaging device according to one embodiment of the present disclosure includes a light guide member, a first photoelectric conversion element, and a second photoelectric conversion element. The light guide member includes a plurality of first structures. The first photoelectric conversion element photoelectrically converts light that enters through the light guide member. The second photoelectric conversion element photoelectrically converts infrared light that enters through the first photoelectric conversion element.

An electronic apparatus according to one embodiment of the present disclosure includes an imaging device. The imaging device includes a first photoelectric conversion element, a light guide member, and a second photoelectric conversion element. The first photoelectric conversion element photoelectrically converts light. The light guide member includes a plurality of first structures. Infrared light transmitted through the first photoelectric conversion element enters the light guide member. The second photoelectric conversion element photoelectrically converts the infrared light that enters through the light guide member.

### BRIEF DESCRIPTION OF DRAWINGS

FIG. 1 is a block diagram illustrating an example of a schematic configuration of an imaging device according to an embodiment of the present disclosure.

FIG. 2 is a diagram illustrating an example of a pixel section of the imaging device according to the embodiment of the present disclosure.

FIG. 3 is a diagram illustrating an example of a sectional configuration of the imaging device according to the embodiment of the present disclosure.

FIG. 4A is a diagram illustrating an example of a planar configuration of the imaging device according to the embodiment of the present disclosure.

FIG. 4B is a diagram illustrating an example of a planar configuration of the imaging device according to the embodiment of the present disclosure.

FIG. 4C is a diagram illustrating an example of a planar configuration of the imaging device according to the embodiment of the present disclosure.

FIG. 5 is a diagram illustrating a configuration example of the imaging device according to the embodiment of the present disclosure.

FIG. 6 is a diagram describing a configuration example of the imaging device according to the embodiment of the present disclosure.

FIG. 7A is a diagram describing an example of a manufacturing method of the imaging device according to the embodiment of the present disclosure.

FIG. 7B is a diagram describing an example of the manufacturing method of the imaging device according to the embodiment of the present disclosure.

FIG. 7C is a diagram describing an example of the manufacturing method of the imaging device according to the embodiment of the present disclosure.

FIG. 7D is a diagram describing an example of the manufacturing method of the imaging device according to the embodiment of the present disclosure.

FIG. 8 is a diagram illustrating an example of a sectional configuration of an imaging device according to Modification example 1 of the present disclosure.

FIG. 9 is a diagram illustrating another example of the sectional configuration of the imaging device according to Modification example 1 of the present disclosure.

FIG. 10 is a diagram illustrating an example of a sectional configuration of an imaging device according to Modification example 2 of the present disclosure.

FIG. 11 is a diagram illustrating an example of a sectional configuration of an imaging device according to Modification example 3 of the present disclosure.

FIG. 12 is a diagram illustrating an example of a sectional configuration of an imaging device according to Modification example 4 of the present disclosure.

FIG. 13 is a diagram illustrating an example of a sectional configuration of an imaging device according to Modification example 5 of the present disclosure.

FIG. 14 is a diagram illustrating an example of a sectional configuration of an imaging device according to Modification example 6 of the present disclosure.

FIG. 15 is a block diagram illustrating a configuration example of an electronic apparatus including an imaging device.

FIG. 16 is a block diagram depicting an example of schematic configuration of a vehicle control system.

FIG. 17 is a diagram of assistance in explaining an example of installation positions of an outside-vehicle information detecting section and an imaging section.

FIG. 18 is a view depicting an example of a schematic configuration of an endoscopic surgery system.

FIG. 19 is a block diagram depicting an example of a functional configuration of a camera head and a camera control unit (CCU).

### MODES FOR CARRYING OUT THE INVENTION

Hereinafter, an embodiment of the present disclosure will be described in detail with reference to the drawings. It is to be noted that description is given in the following order.
1. Embodiment
2. Modification Examples
3. Application Example
4. Practical Application Example

### 1. Embodiment

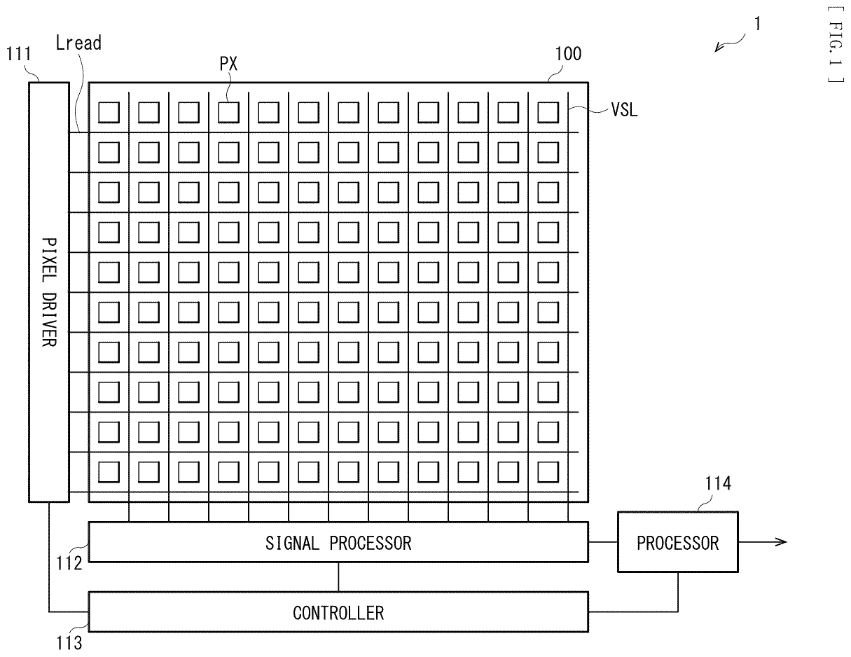

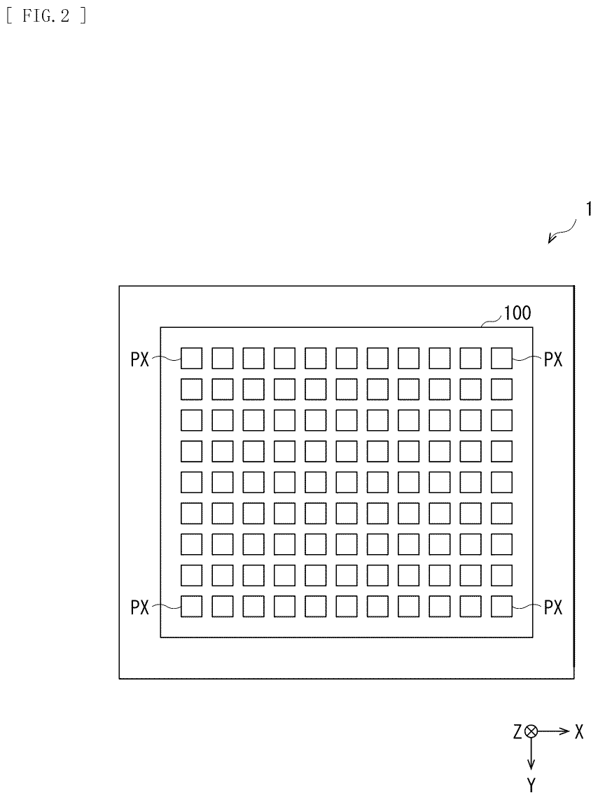

FIG. 1 is a block diagram illustrating an example of a schematic configuration of an imaging device according to an embodiment of the present disclosure. FIG. 2 is a diagram illustrating an example of a pixel section of the imaging device according to the embodiment. An imaging device 1 includes a plurality of pixels PX including a photoelectric conversion section (a photoelectric conversion element), and is configured to photoelectrically convert incident light to generate a signal. The imaging device 1 may receive light transmitted through an optical system (unillustrated) including an optical lens and generate a signal.

The photoelectric conversion section of each of the pixels PX of the imaging device 1 is, for example, a photodiode (PD), and is configured to photoelectrically convert the light. As in the example illustrated in FIG. 2, the imaging device 1 includes, as an imaging area, a region (a pixel section 100) in which the plurality of pixels PX is two-dimensionally arranged in a matrix. The pixel section 100 is a pixel array in which the plurality of pixels PX is arranged, and may also be referred to as a light receiving region.

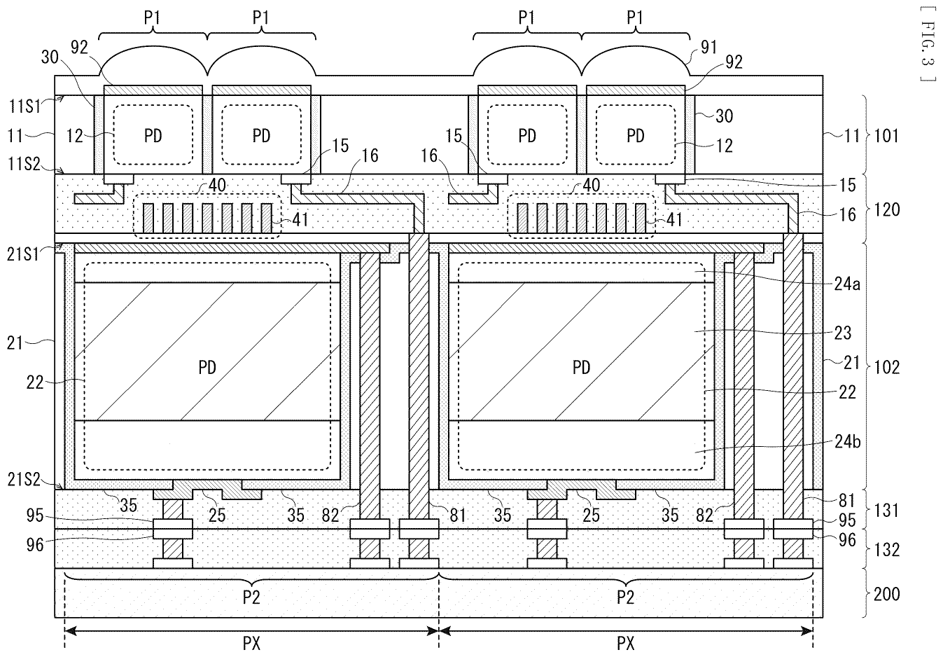

Each of the pixels PX of the pixel section 100 includes pixels P1 and a pixel P2, which will be described later (see, e.g., FIG. 3). For example, the pixel P1 is a pixel including a photoelectric conversion section that receives visible light and performs photoelectric conversion. The pixel P2 is a pixel (an IR pixel) including a photoelectric conversion section that receives infrared light and performs photoelectric conversion. The pixel PX has a structure (a stacked structure) including a photoelectric conversion section that photoelectrically converts visible light and a photoelectric conversion section that photoelectrically converts infrared light, that are stacked on one another.

The imaging device 1 takes in incident light (image light) from a subject via the optical system including the optical lens. The imaging device 1 captures an image of the subject formed by the optical lens. The imaging device 1 may photoelectrically convert the received light to generate pixel signals. The imaging device 1 is, for example, a CMOS (Complementary Metal Oxide Semiconductor) image sensor.

The imaging device 1 is a device configured to receive incident light and generate a signal, and may also be referred to as a light receiver (or a photodetector). The imaging device 1 is usable, for example, in various electronic apparatuses having an imaging function, such as a digital still camera, a video camera, or a mobile phone.

As illustrated in FIG. 2, an incident direction of light from the subject is defined as a Z-axis direction, a left-right direction on the paper plane orthogonal to the Z-axis direction is defined as an X-axis direction, and an up-down direction on the paper plane orthogonal to the Z-axis direction and the X-axis direction is defined as a Y-axis direction. In the following drawings, the direction may be expressed with reference to the directions of the arrows in FIG. 2.

As in the example illustrated in FIG. 1, the imaging device 1 includes, for example, a pixel driver 111, a signal processor 112, a controller 113, and a processor 114 in a peripheral region of the pixel section 100 (the pixel array). The imaging device 1 is provided with, for example, a plurality of control lines Lread and a plurality of signal lines VSL.

The control lines Lread are signal lines configured to transmit signals that control the pixels PX. The control lines Lread are coupled to the pixel driver 111 and to the pixels PX of the pixel section 100. In the example illustrated in FIG. 1, the plurality of control lines Lread is wired in the pixel section 100 for each pixel row including the plurality of pixels PX arranged in a horizontal direction (a row direction). The control lines Lread are configured to transmit control signals adapted to read out signals from the pixels PX.

The plurality of control lines Lread provided for each pixel row of the imaging device 1 includes, for example, a wiring that transmits a signal to control a transfer transistor, a wiring that transmits a signal to control a selection transistor, a wiring that transmits a signal to control a reset transistor, and the like. The control lines Lread may also be referred to as drive lines (pixel drive lines) that transmit signals to drive the pixels PX.

The signal lines VSL are signal lines configured to transmit signals from the pixels PX, and are coupled to the pixels PX of the pixel section 100 and to the signal processor 112. For example, one or a plurality of signal lines VSL is wired in the pixel section 100 for each pixel column including the plurality of pixels PX arranged in a vertical direction (a column direction).

The signal lines VSL are vertical signal lines and are configured to transmit signals outputted from the pixels PX. In the imaging device 1, a plurality of signal lines VSL may be provided for one pixel column. The imaging device 1 may include a plurality of signal lines VSL for each pixel column.

The pixel driver 111 is configured to drive the pixels PX of the pixel section 100. The pixel driver 111 is a driver circuit and includes a plurality of circuits including, for example, a buffer, a shift register, an address decoder, and the like. The pixel driver 111 generates signals adapted to drive the pixels PX, and outputs the signals to the pixels PX of the pixel section 100 via the control lines Lread. The pixel driver 111 is controlled by the controller 113 and controls the pixels PX of the pixel section 100.

For example, the pixel driver 111 generates signals adapted to control the pixels PX including, for example, a signal that controls the transfer transistor of the pixel PX, a signal that controls the selection transistor of the pixel PX, and a signal that controls the reset transistor of the pixel PX, and supplies the generated signals to the pixels PX through the control lines Lread. The pixel driver 111 may perform control to read out the pixel signals from the pixels PX. The pixel driver 111 may also be referred to as a pixel controller configured to control the pixels PX. The pixel driver 111 and the controller 113 may together be referred to as the pixel controller.

The signal processor 112 is configured to perform signal processing on signals from the pixels that have been received. The signal processor 112 is a signal processing circuit and includes, for example, a load circuit, an AD (Analog Digital) converter, a horizontal selection switch, and the like. The signal processor 112 may include an amplifier circuit configured to amplify signals read out from the pixels PX via the signal lines VSL.

The signals outputted from the pixels PX selected and scanned by the pixel driver 111 are inputted to the signal processor 112 via the signal lines VSL. The signal processor 112 may perform signal processing including, for example, AD conversion of signals from the pixels PX, CDS (Correlated Double Sampling), and the like. The signals from the pixels PX transmitted through the respective signal lines VSL are subjected to signal processing by the signal processor 112 and outputted to the processor 114.

The processor 114 is configured to perform signal processing on the signals that have been received. The processor 114 is a signal processing circuit and includes, for example, a circuit that performs various types of signal processing on the pixel signals. The processor 114 may include a processor and a memory. The processor 114 performs signal processing on the signals from the pixels received from the signal processor 112, and outputs the signals from the pixels that have been processed. The processor 114 may perform various types of signal processing including, for example, noise reduction processing and gradation correction processing.

The controller 113 is configured to control each section of the imaging device 1. The controller 113 may receive a clock supplied from the outside, data that commands an operation mode, and the like, and also output data such as internal information regarding the imaging device 1. The controller 113 is a control circuit, and includes, for example, a timing generator configured to generate various timing signals.

The controller 113 controls driving of the pixel driver 111, the signal processor 112, and the like on the basis of the various timing signals (e.g., pulse signals and clock signals) generated by the timing generator. Note that the controller 113 and the processor 114 may be integrally formed.

The pixel driver 111, the signal processor 112, the controller 113, the processor 114, and the like may be provided on one semiconductor substrate or may be provided separately on a plurality of semiconductor substrates. The imaging device 1 may have a stacked structure including a plurality of substrates stacked on one another.

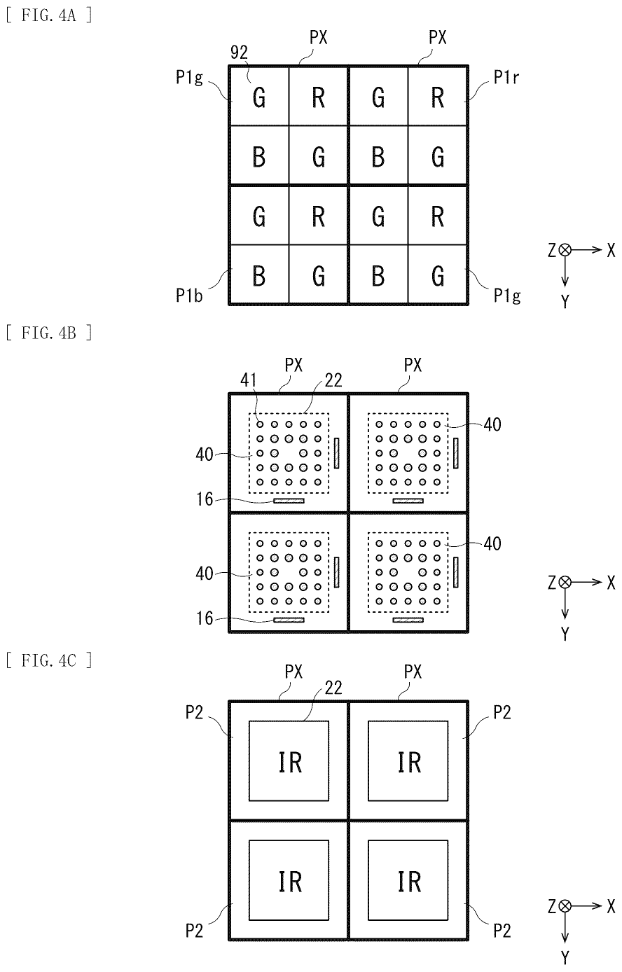

FIG. 3 is a diagram illustrating an example of a sectional configuration of the imaging device according to the embodiment. FIGS. 4A to 4C are diagrams illustrating an example of a planar configuration of the imaging device according to the embodiment. As illustrated in FIG. 3, the imaging device 1 includes, for example, lenses 91, filters 92, a first light receiving section 101, an insulating layer 120, a second light receiving section 102, a wiring layer 131, a wiring layer 132, and a circuit layer 200. FIG. 4A illustrates an example of a planar configuration of the first light receiving section 101. FIG. 4B illustrates an example of a planar configuration of the insulating layer 120, and FIG. 4C illustrates an example of a planar configuration of the second light receiving section 102.

As illustrated in FIG. 3, the imaging device 1 includes, for example, the lenses 91, the filters 92, the first light receiving section 101, the insulating layer 120, the second light receiving section 102, the wiring layer 131, the wiring layer 132, and the circuit layer 200 that are stacked in the Z-axis direction. The lenses 91, the filters 92, the first light receiving section 101, the insulating layer 120, the second light receiving section 102, the wiring layer 131, the wiring layer 132, and the circuit layer 200 are provided from the light incident side.

The pixel PX of the imaging device 1 includes the pixels P1 and the pixel P2. The pixel P1 includes a first photoelectric conversion section 12. The pixel P2 includes a second photoelectric conversion section 22. The pixel PX has a configuration in which the first photoelectric conversion section 12 and the second photoelectric conversion section 22 are stacked on one another. The pixel PX may also be regarded as having a configuration in which the pixel P1 and the pixel P2 are stacked on one another.

As illustrated in FIG. 3, the first light receiving section 101 includes a first semiconductor layer 11 including a first surface 11S1 and a second surface 11S2 that are opposed to each other. The second surface 11S2 is a surface opposite to the first surface 11S1. The first semiconductor layer 11 includes a semiconductor substrate such as a Si (silicon) substrate. The first semiconductor layer 11 may be a substrate such as a SOI (Silicon On Insulator) substrate or a SiGe (silicon germanium) substrate, or may include other semiconductor material.

The first surface 11S1 of the first semiconductor layer 11 is a light-receiving surface (a light-incidence surface). The second surface 11S2 of the first semiconductor layer 11 is an element forming surface on which an element such as a transistor is formed. A gate electrode, a gate oxide film, and the like may be provided on the second surface 11S2 of the first semiconductor layer 11.

In the example illustrated in FIG. 3, the lenses 91 and the filters 92 are provided on the first surface 11S1 of the first semiconductor layer 11. The lenses 91, the filters 92, and the like are provided on a side on which light from the optical system enters. The insulating layer 120 (a wiring layer) is provided on the second surface 11S2 of the first semiconductor layer 11.

In the first light receiving section 101, a plurality of first photoelectric conversion sections 12 (photoelectric conversion elements) are provided along the first surface 11S1 and the second surface 11S2 of the first semiconductor layer 11. For example, the plurality of first photoelectric conversion sections 12 is embedded in the first semiconductor layer 11.

The first photoelectric conversion sections 12 are configured to generate electric charges by photoelectric conversion. In the example illustrated in FIG. 3, the first photoelectric conversion sections 12 are photodiodes (PD) and convert incident light into electric charges. The first photoelectric conversion sections 12 include, for example, an inorganic material such as silicon. Each of the pixels P1 of the imaging device 1 includes a photodiode PD as the first photoelectric conversion section 12.

The first photoelectric conversion section 12 of the pixel P1 is, for example, configured to receive visible light and generate an electric charge. The first photoelectric conversion section 12 performs photoelectric conversion to generate an electric charge corresponding to the amount of received light. The first light receiving section 101 (or the first semiconductor layer 11) may also be referred to as a first photoelectric conversion layer.

The first photoelectric conversion section 12 may include an inorganic material or an organic material. The first photoelectric conversion section 12 may include quantum dots. For example, a photoelectric conversion film including an organic material may be provided as the first photoelectric conversion section 12. The first photoelectric conversion section 12 may be a photoelectric conversion film including an inorganic material or may include quantum dots.

The second light receiving section 102 includes a second semiconductor layer 21 including a first surface 21S1 and a second surface 21S2 that are opposed to each other. The second surface 21S2 is a surface opposite to the first surface 21S1. The insulating layer 120 is provided on the first surface 21S1 of the second semiconductor layer 21, and the wiring layer 131 is provided on the second surface 21S2 of the second semiconductor layer 21. The wiring layer 131 is provided on a side opposite to the light incident side.

The second semiconductor layer 21 includes, for example, a compound semiconductor material. The second semiconductor layer 21 includes, for example, a material such as InGaAs, InP, or AlGaAs. The second semiconductor layer 21 may be configured by a semiconductor substrate including a compound semiconductor such as InGaAs, or may include other semiconductor material.

In the second light receiving section 102, a plurality of second photoelectric conversion sections 22 (the photoelectric conversion elements) is provided along the first surface 21S1 and the second surface 21S2 of the second semiconductor layer 21. For example, the plurality of second photoelectric conversion sections 22 is embedded in the second semiconductor layer 21.

The second photoelectric conversion sections 22 are configured to generate electric charges by photoelectric conversion. The second photoelectric conversion sections 22 are, for example, photodiodes (PD) and convert incident light into electric charges. Each of the pixels P2 of the imaging device 1 includes a photodiode PD as the second photoelectric conversion section 22.

The second photoelectric conversion section 22 includes, for example, a compound semiconductor material. The second photoelectric conversion section 22 may include a semiconductor material such as InGaAs or InP, or may include other material. The second photoelectric conversion section 22 may include quantum dots.

The second photoelectric conversion section 22 of the pixel P2 is, for example, configured to receive infrared light and generate an electric charge. The second photoelectric conversion section 22 performs photoelectric conversion to generate an electric charge corresponding to the amount of received light. The second light receiving section 102 (or the second semiconductor layer 21) may also be referred to as a second photoelectric conversion layer.

In the example illustrated in FIG. 3, the second photoelectric conversion section 22 includes a semiconductor region 23 and semiconductor regions 24a and 24b. The second photoelectric conversion section 22 includes the semiconductor region 24a, the semiconductor region 23, and the semiconductor region 24b stacked on one another. In one example, the semiconductor region 23 includes InGaAs. Each of the semiconductor regions 24a and 24b includes InP. For example, the semiconductor region 24b and the semiconductor region 23 are doped with p-type or n-type impurities to form the second photoelectric conversion section 22 that is a photodiode.

The lenses 91 and the filters 92 are stacked on the first light receiving section 101 in a thickness direction perpendicular to the first surface 11S1 of the first semiconductor layer 11. The lens 91 guides light that enters from above to the first light receiving section 101. The lens 91 (a lens section) is an optical member also called an on-chip lens.

The lens 91 is provided above the filter 92 for each pixel P1 or for a plurality of pixels P1, for example. Light from the subject enters the lens 91 via an optical system such as an imaging lens. The first photoelectric conversion section 12 photoelectrically converts light that enters through the lens 91 and the filter 92.

The imaging device 1 may include the filters 92 as in the example illustrated in FIG. 3. The filter 92 is configured to selectively transmit light in a specific wavelength range of the incident light. The filter 92 is, for example, an RGB color filter. The filter 92 is provided above the first photoelectric conversion section 12 for each pixel P1 or for a plurality of pixels P1, for example.

The plurality of pixels P1 provided in the pixel section 100 of the imaging device 1 includes a plurality of pixels P1r provided with filters 92 that transmit red (R) light, a plurality of pixels P1g provided with filters 92 that transmit green (G) light, and a plurality of pixels P1b provided with filters 92 that transmit blue (B) light.

In the pixel section 100, as illustrated in FIG. 4A, the plurality of pixels P1r, the plurality of pixels P1g, and the plurality of pixels P1b are repeatedly arranged. In one example, the pixels P1r, the pixels P1g, and the pixels P1b are arranged according to a Bayer array. A 2×2 pixel unit including one pixel P1r, two pixels P1g, and one pixel P1b is repeatedly provided.

The pixel P1r, the pixel P1g, and the pixel P1b may each be arranged in 2×2 pixel units. For example, in the pixel section 100, four adjacent pixels P1r, four adjacent pixels P1g, and four adjacent pixels P1b are repeatedly arranged. The pixels P1r, the pixels P1g, and the pixels P1b may be regarded as each being periodically arranged in a 2-row by 2-column pattern.

The pixels P1r, the pixels P1g, and the pixels P1b respectively generate a pixel signal of an R component, a pixel signal of a G component, and a pixel signal of a B component. It is possible for the imaging device 1 to obtain RGB pixel signals. Note that the arrangement of the pixels P1 is not limited to the above-described example, and may be set as desired.

The filters 92 provided in the pixels P1 of the pixel section 100 are not limited to color filters of a primary color system (RGB) and may be, for example, a complementary color filter such as Cy (cyan), Mg (magenta), or Ye (yellow). A filter corresponding to W (white), that is, a filter that transmits light in the entire wavelength range of the incident light may be provided.

In the imaging device 1, the filters 92 may be omitted as necessary. For example, in a pixel that receives white (W) light and performs photoelectric conversion, the filter 92 may not be provided. Further, the filter 92 may not be provided in all or a part of the pixels of the imaging device 1.

In the pixel section 100, the pixel P2 is provided for each pixel P1 or for a plurality of pixels P1. In the example illustrated in FIGS. 4A to 4C, one pixel P2 is provided for four pixels P1 in a 2×2 pattern. The pixel P2 that is the IR pixel has, for example, a size corresponding to four pixels P1.

The pixel PX includes, for example, four pixels P1 and one pixel P2. The area of the second photoelectric conversion section 22 of the pixel P2 is larger than the area of the first photoelectric conversion section 12 of the pixel P1. In the pixel section 100 of the imaging device 1, one pixel P2 may be provided for one pixel P1. The pixel PX may include one pixel P1 and one pixel P2.

The imaging device 1 is provided with separators 30 as in the example illustrated in FIG. 3. The separator 30 is provided between the plurality of first photoelectric conversion sections 12 adjacent to each other, and separate the first photoelectric conversion sections 12 from each other. As an example, the separator 30 is provided to surround the first photoelectric conversion sections 12 in the first semiconductor layer 11.

The separator 30 is configured by a trench (groove) provided at a boundary between the adjacent pixels P1 (or the first photoelectric conversion sections 12). For example, the separator 30 is provided to surround each of the first photoelectric conversion sections 12 in the first semiconductor layer 11. The separator 30 may be provided in a grid shape to surround each of the first photoelectric conversion sections 12.

The separator 30 is provided to extend through the first semiconductor layer 11, for example, as illustrated in FIG. 3. As an example, an insulating film such as a silicon oxide film is provided in the trench of the separator 30. Note that, polysilicon, a metallic material, or the like may be embedded in the trench of the separator 30.

The separator 30 may include other dielectric material having a low refractive index. For example, a gap (cavity) may be provided in the trench of the separator 30. Providing the separator 30 suppresses leakage of the electric charge photoelectrically converted by the first photoelectric conversion section 12 of the pixel P1 to the surrounding pixels P1.

The insulating layer 120 is provided between the first semiconductor layer 11 and the second semiconductor layer 21. The insulating layer 120 is provided to be stacked on the second semiconductor layer 21 and is positioned on the first surface 21S1 of the second semiconductor layer 21. The insulating layer 120 includes, for example, an insulating film such as an oxide film, a nitride film, or an oxynitride film.

The insulating layer 120 includes, for example, silicon oxide (SiO). The insulating layer 120 may include silicon oxynitride (SiON), silicon nitride (SiN), or the like. The insulating layer 120 may include a low refractive index material such as silicon oxide, or may include other material that transmits infrared light.

The insulating layer 120 includes a wiring layer and includes a plurality of wirings, vias (VIA), and the like. The insulating layer 120 (the wiring layer) includes, for example, a conductive film and an insulating film, and includes one layer, or two or more layers of wirings. The insulating layer 120 has a configuration in which multiple wirings are stacked with an insulating film interposed therebetween. The insulating film of the insulating layer 120 may also be referred to as an interlayer insulating film.

The wirings of the insulating layer 120 include, for example, polysilicon (Poly-Si). The wirings of the insulating layer 120 may include a metallic material such as aluminum (Al), copper (Cu), or tungsten (W), or other conductive material. The interlayer insulating film includes, for example, silicon oxide (SiO), silicon nitride (SiN), silicon oxynitride (SiON), or the like.

As illustrated in FIG. 3, the imaging device 1 includes an insulating film 35. The insulating film 35 is provided to cover the periphery of the second photoelectric conversion section 22 in the second semiconductor layer 21. In the second semiconductor layer 21, the insulating film 35 is formed along the semiconductor region 23 and the semiconductor regions 24a and 24b of the second photoelectric conversion section 22. A part of the insulating film 35 is provided between the second semiconductor layer 21 and the insulating layer 120, and another part of the insulating film 35 is provided between the second semiconductor layer 21 and the wiring layer 131.

Each of the wiring layer 131 and the wiring layer 132 includes, for example, a conductive film and an insulating film, and includes a plurality of wirings, vias, and the like. The wiring layer 131 and the wiring layer 132 include one layer, or two or more layers of wirings. Each of the wiring layer 131 and the wiring layer 132 has a configuration in which multiple wirings are stacked with an insulating film (an interlayer insulating film) interposed therebetween.

The wiring of each of the wiring layer 131 and the wiring layer 132 includes, for example, a metallic material such as aluminum (Al), copper (Cu), or tungsten (W). The wirings of the wiring layers 131 and 132 may include polysilicon (Poly-Si) or other conductive material. The interlayer insulating film includes, for example, silicon oxide, silicon nitride, silicon oxynitride, or the like.

Electrodes 25 electrically coupled to the second photoelectric conversion sections 22 are provided in the wiring layer 131. The electrodes 25 are provided on the second surface 21S2 of the second semiconductor layer 21 and are electrically coupled to the semiconductor regions 24b of the second photoelectric conversion sections 22. The electrodes 25 of the pixels P2 include, for example, a metallic material such as tungsten (W). The electrodes 25 electrically couple the second photoelectric conversion sections 22 and a circuit provided in the circuit layer 200 to each other.

Further, a plurality of electrodes 95 is provided in the wiring layer 131, and a plurality of electrodes 96 is provided in the wiring layer 132. The electrodes 95 and the electrodes 96 are each an electrode including, for example, copper (Cu). The electrodes 95 and 96 are electrodes used for bonding between metal electrodes, and may also be referred to as bonding electrodes. For example, the second semiconductor layer 21 and the circuit layer 200 are bonded to each other by bonding between the metal electrodes (the electrodes 95 and the electrodes 96) including Cu, that is, by Cu—Cu bonding.

The circuit of the second semiconductor layer 21 and the circuit of the circuit layer 200 are electrically coupled to each other by the electrodes 95 and the electrodes 96. The electrodes 95 and 96 may include a metallic material other than copper, for example, nickel (Ni), cobalt (Co), gold (Au), or the like. Alternatively, the second semiconductor layer 21 and the circuit layer 200 may be stacked on one another using bumps.

The imaging device 1 includes a plurality of through-electrodes 81 and a plurality of through-electrodes 82. The through-electrodes 81 and the through-electrodes 82 are each a coupling electrode (a coupling section) and couples circuits provided in different layers. The through-electrodes 81 and 82 are provided to extend through the second semiconductor layer 21.

The through-electrodes 81 and the through-electrodes 82 are each formed to reach the second surface 21S2 of the second semiconductor layer 21, for example, between the plurality of second photoelectric conversion sections 22 adjacent to each other, thereby extending through the second semiconductor layer 21. The through-electrodes 81 and 82 are formed to extend in the Z-axis direction and reach the inside of the wiring layer 131.

The through-electrodes 81 and the through-electrodes 82 each include, for example, tungsten (W). The through-electrodes 81 and the through-electrodes 82 may each include copper (Cu), aluminum (Al), cobalt (Co), molybdenum (Mo), ruthenium (Ru), or the like. The through-electrodes 81 and 82 may include other metallic material.

The imaging device 1 is provided with readout circuits configured to output pixel signals based on the electric charges generated by the first photoelectric conversion sections 12 or the second photoelectric conversion sections 22. For example, the readout circuits are distributed to the first semiconductor layer 11, the second semiconductor layer 21, the circuit layer 200, and the like.

For example, the readout circuit includes a transfer transistor, a floating diffusion (FD), a reset transistor, an amplifier transistor, a selection transistor, and the like. At least a part of the readout circuit may be provided in the first semiconductor layer 11 and the insulating layer 120.

The readout circuit of the pixel PX is configured to read out the pixel signals based on the electric charges converted by the first photoelectric conversion sections 12 to the above-described signal line VSL. Further, the readout circuit is configured to read out the pixel signal based on the electric charge converted by the second photoelectric conversion section 22 to the signal line VSL. The pixel driver 111 (see FIG. 1) may read out the pixel signals from each pixel PX to the signal line VSL by controlling the readout circuit of each pixel PX.

In the example illustrated in FIG. 3, electrodes 15 and wirings 16 provided for the first photoelectric conversion sections 12 of the pixels P1 are illustrated. The electrodes 15 and the wirings 16 are, for example, electrodes and wirings used to read out the electric charges converted by the first photoelectric conversion sections 12.

The electrode 15 is, for example, an electrode (a source electrode or a drain electrode) of the transfer transistor in the above-described readout circuit. When the first photoelectric conversion section 12 is configured by a photoelectric conversion film, the electrode 15 is, for example, an electrode electrically coupled to the photoelectric conversion film.

In the imaging device 1, the electrode 15 of the pixel P1 and the circuit provided in the circuit layer 200 are electrically coupled by the wiring 16, the through-electrode 81, and the like. The electrode 15 of the pixel P1 is electrically coupled to the circuit provided in the circuit layer 200 via the wiring 16, the through-electrode 81, the electrode 95, and the like.

Further, in the imaging device 1, the second photoelectric conversion section 22 of the pixel P2 and the circuit provided in the circuit layer 200 are electrically coupled to each other. The electrode 25 coupled to the semiconductor region 24b of the second photoelectric conversion section 22 is electrically coupled to the circuit provided in the circuit layer 200 via the electrode 95.

The semiconductor region 24a of the second photoelectric conversion section 22 is electrically coupled to the circuit provided in the circuit layer 200 via the through-electrode 82, the electrode 95, and the like. The circuit layer 200 and the wiring layer 132 may be provided with, for example, the readout circuits, the pixel driver 111, the signal processor 112, the controller 113, the processor 114, and the like described above.

As illustrated in FIGS. 3 and 4B, the imaging device 1 includes light guide sections 40. The light guide section 40 (a light guide member) is provided between the first photoelectric conversion sections 12 and the second photoelectric conversion section 22. The light guide section 40 includes structures 41 and is configured to guide the incident light toward the second photoelectric conversion section 22.

Light from the subject to be measured enters the light guide section 40 of each of the pixels PX of the imaging device 1 via the first photoelectric conversion sections 12. Infrared light transmitted through the first photoelectric conversion sections 12 enters a plurality of structures 41 of the light guide section 40. The structures 41 are structures having a size smaller than or equal to a predetermined wavelength of incident light.

The structures 41 have, for example, a size smaller than or equal to a wavelength range of infrared light. The structures 41 may have a size smaller than or equal to a wavelength range of short-wave infrared (SWIR). Alternatively, the structures 41 may have a size smaller than or equal to a wavelength range of near-infrared light, or may have a size smaller than or equal to a wavelength range of visible light.

The structures 41 are, for example, columnar (pillar-shaped) structures. In the example illustrated in FIGS. 3 and 4B, the structures 41 have a cylindrical shape. The structures 41 may have a rectangular prism shape. The shape of the structures 41 of the light guide section 40 may be changed as appropriate. The shape of the structures 41 may be a rectangular shape in plan view. In addition, the shape of the structures 41 may be a polygonal shape, an ellipse shape, a cross shape, or other shape.

In the imaging device 1, the plurality of structures 41 is provided in the insulating layer 120 between the first photoelectric conversion sections 12 and the second photoelectric conversion section 22. The structures 41 of the light guide section 40 are provided in the insulating layer 120 around the electrodes 15 and the wirings 16 of the pixels P1. In the example illustrated in FIG. 3, the plurality of structures 41 is provided in a region between the respective wirings 16 of the plurality of pixels P1.

The insulating film of the insulating layer 120 is provided to fill spaces between the plurality of structures 41 adjacent to each other. The insulating film of the insulating layer 120 is a silicon oxide film or the like, and is embedded between the structures 41. The insulating film may be formed to cover the structures 41. The structures 41 may also be regarded as being provided in the insulating layer 120 to be replaced with a part of the insulating layer 120.

The light guide section 40 (the light guide member) uses the structures 41 that are nanostructures to propagate light to the second photoelectric conversion section 22. The structures 41 are also referred to as microstructures, meta-atoms, nano-atoms, nano-posts, or the like. The light guide section 40 is an optical element (an optical member) that guides (propagates) light.

The light guide section 40 is configured as, for example, a deflection element (a deflection section) that deflects light. The light guide section 40 may be configured to provide a phase delay to the incident light and deflect the light. The light guide section 40 may be, for example, provided for each pixel P2 or for a plurality of pixels P2.

In the example illustrated in FIG. 3, the structures 41 of the light guide section 40 are pillars (columnar members) and are provided on the first surface 21S1 of the second semiconductor layer 21. The plurality of structures 41 is provided side by side in the X-axis direction with a part of the insulating layer 120 interposed therebetween. For example, as in the example illustrated in FIG. 4B, the plurality of structures 41 of the light guide section 40 may be provided side by side in the X-axis direction and the Y-axis direction intersecting the X-axis direction, in a plan view. The plurality of structures 41 is regularly aligned.

In each of the pixels PX of the imaging device 1, the plurality of structures 41 may be arranged with a spacing less than or equal to a predetermined wavelength of incident light, for example, less than or equal to a wavelength of infrared light. For instance, in the imaging device 1, as in the example illustrated in FIG. 4B, the plurality of structures 41 is provided with a spacing less than or equal to the wavelength range of short-wave infrared light in the X-axis direction and the Y-axis direction. Note that the plurality of structures 41 may be arranged with a spacing less than or equal to the wavelength range of the near-infrared light (or visible light).

The structures 41 of the light guide section 40 have a refractive index different from the refractive index of the adjacent medium. In the example illustrated in FIG. 3, the structures 41 have a refractive index different from the refractive index of the insulating layer 120. The structures 41 have a refractive index different from the refractive index of the insulating film of the insulating layer 120 formed around the structures 41.

The structures 41 of the light guide section 40 have, for example, a refractive index higher than the refractive index of the insulating layer 120. The structures 41 may include a material having a refractive index higher than the refractive index of the insulating film (e.g., a silicon oxide film) of the insulating layer 120. The structures 41 include, for example, silicon, polysilicon (Poly-Si), or the like. The structures 41 may include amorphous silicon (a-Si).

The structures 41 may include a simple substance such as titanium, hafnium, zirconium, tantalum, aluminum, niobium, or indium, an oxide, a nitride, an oxynitride, or a composite thereof. For example, the structures 41 may include a metal compound (e.g., metal oxide and metal nitride) such as titanium oxide (TiO).

The material of the structures 41 may be selected in accordance with the difference in the refractive index with the surrounding medium and the wavelength range of the incident light to be measured. Note that each of the structures 41 of the light guide section 40 may include an inorganic material or an organic material.

The structures 41 may include, for example, the same material as the wirings provided in the insulating layer 120. In the example illustrated in FIGS. 3 and 4B, the structures 41 may include the same material as the material included in the wirings 16 described above. The structures 41 may include the same material as the wirings 16, for example, polysilicon. The structures 41 include the same material as the wirings 16, and has a refractive index higher than the refractive index of the insulating film of the insulating layer 120.

It is possible for the light guide section 40 to cause a phase delay in the incident light by the difference in the refractive index between the structures 41 and the medium surrounding the structures 41, thereby affecting the wavefront. It is possible for the light guide section 40 to adjust a propagation direction of light by, for example, applying a phase delay to the incident light by the structures 41 and the insulating film of the insulating layer 120 around the structures 41.

A material (an optical constant of each material), size, pitch (arrangement spacing), shape, and the like of the plurality of structures 41 are determined to cause light in a given wavelength range included in the incident light to travel in a desired direction. In the example illustrated in FIGS. 3 and 4B, the material (refractive index), sizes (e.g., width and height), pitch, shape, and the like of the structures 41 of the light guide section 40 may be set. Note that the arrangement position of the structures 41, the size dimension of the structures 41, and the like may be changed depending on the position of the pixel PX in the pixel section 100.

The light guide section 40 is an optical element that uses a metamaterial (metasurface) technology, and may also be referred to as a light guide element configured to guide light. The light guide section 40 may be configured as, for example, an optical element (a deflector) that changes the traveling direction of light in a specific wavelength range.

The propagation direction of the light by the light guide section 40 is adjustable in accordance with the material, shape, height, arrangement position, and the like of the structures 41. For example, the material, size, and the like of the structures 41 are determined to cause light (for example, infrared light) in a wavelength band that is to be detected, to be condensed onto the second photoelectric conversion section 22.

As described above, light from the subject enters the second photoelectric conversion section 22 of each pixel P2 of the imaging device 1 via the light guide section 40. The second photoelectric conversion section 22 of each pixel P2 may receive light that enters through the structures 41 of the light guide section 40, perform photoelectric conversion, and generate an electric charge corresponding to the amount of received light.

Thus, the imaging device 1 may generate pixel signals obtainable by the photoelectric conversion performed by the first photoelectric conversion sections 12 and pixel signals obtainable by the photoelectric conversion performed by the second photoelectric conversion sections 22. This makes it possible for the imaging device 1 to simultaneously obtain the pixel signals based on the amount of received visible light and the pixel signals based on the amount of received infrared light.

It is possible to generate visible images using RGB pixel signals obtainable by photoelectric conversion in each pixel P1. In addition, it is possible to generate an infrared image (for example, a SWIR image) using pixel signals obtainable by photoelectric conversion in each pixel P2.

In the imaging device 1 according to the present embodiment, as described above, the light guide section 40 including the structures 41 is provided between the first photoelectric conversion sections 12 and the second photoelectric conversion section 22. It is therefore possible to appropriately guide the infrared light transmitted through the first photoelectric conversion sections 12 to the second photoelectric conversion section 22. This makes it possible to suppress a decrease in sensitivity to infrared light.

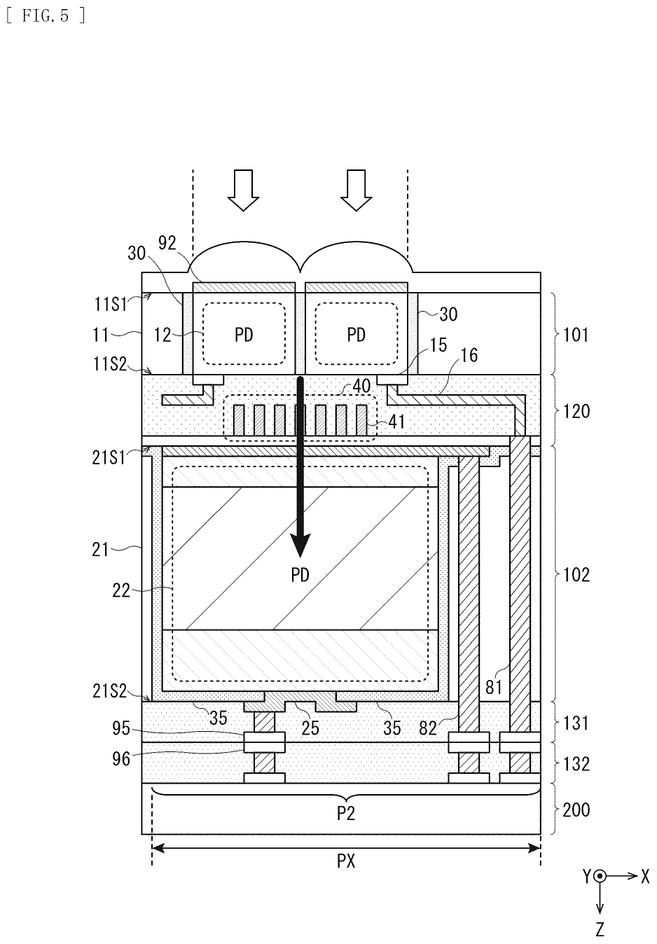

In the present embodiment, with the light guide section 40 being provided, it is possible to efficiently condense light onto the second photoelectric conversion section 22 as schematically illustrated by an arrow in FIG. 5. This makes it possible for the second photoelectric conversion section 22 of the pixel PX to efficiently receive infrared light and perform photoelectric conversion.

Further, with the light guide section 40 being provided between the first photoelectric conversion sections 12 and the second photoelectric conversion section 22, leakage of light to the surrounding pixels is suppressed. This makes it possible to suppress leakage of unnecessary light to the surroundings and to suppress occurrence of color mixture.

Additionally, in the present embodiment, the structures 41 of the light guide section 40 may include the same material as the wirings in the insulating layer 120 (the wiring layer). For example, the structures 41 and the wiring s16 may include polysilicon. In this case, it is possible to form the wirings and the structures 41 in the insulating layer 120 at the same time in the manufacturing process and to reduce the number of processes. This makes it possible to suppress an increase in the manufacturing costs of the imaging device 1.

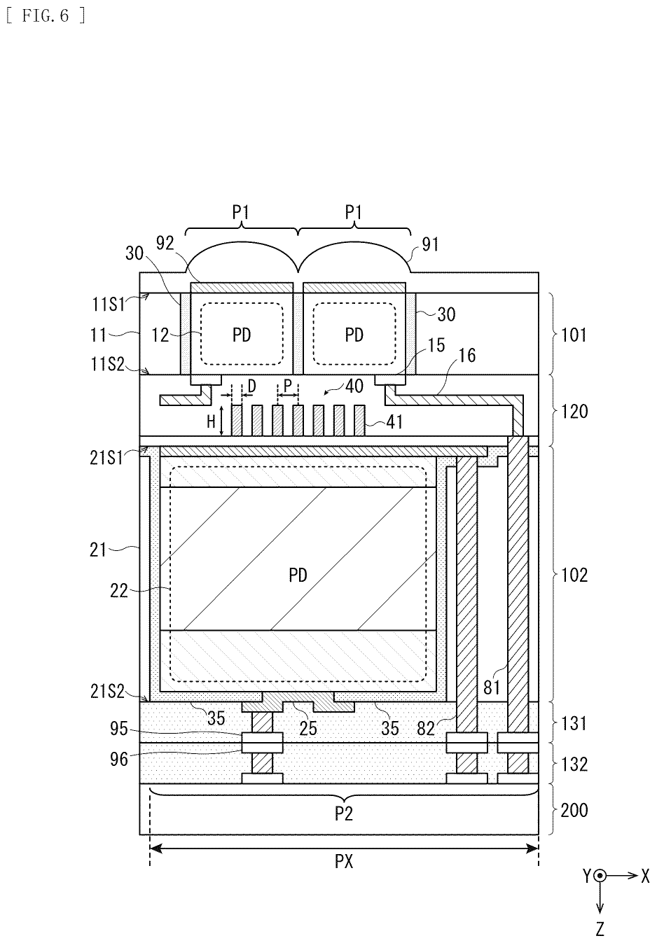

FIG. 6 is a diagram describing a configuration example of the imaging device according to the embodiment. As the example illustrated in FIG. 6, the height (length) H of the structures 41 in the stacking direction (the Z-axis direction in FIG. 6) of the first photoelectric conversion sections 12 and the second photoelectric conversion section 22 may be greater than or equal to 100 nm and less than or equal to 1000 nm.

Additionally, in a direction perpendicular to the stacking direction of the first photoelectric conversion sections 12 and the second photoelectric conversion section 22, the diameter (width) D of the structures 41 may be greater than or equal to 50 nm and less than or equal to 300 nm. Configuring the imaging device 1 as described above makes it possible to efficiently condense light onto the second photoelectric conversion section 22 by the light guide section 40. This makes it possible to suppress a decrease in sensitivity to infrared light.

Additionally, a pitch P of the structures 41 (the arrangement spacing of the structures 41) may be about 400 nm. For example, the pitch P of the structures 41 may be greater than or equal to 350 nm and less than or equal to 450 nm, or greater than or equal to 300 nm and less than or equal to 500 nm. In this case, it is possible for the light guide section 40 to efficiently condense infrared light (short-wave infrared light) onto the second photoelectric conversion section 22. This makes it possible to effectively suppress a decrease in sensitivity to the incident light.

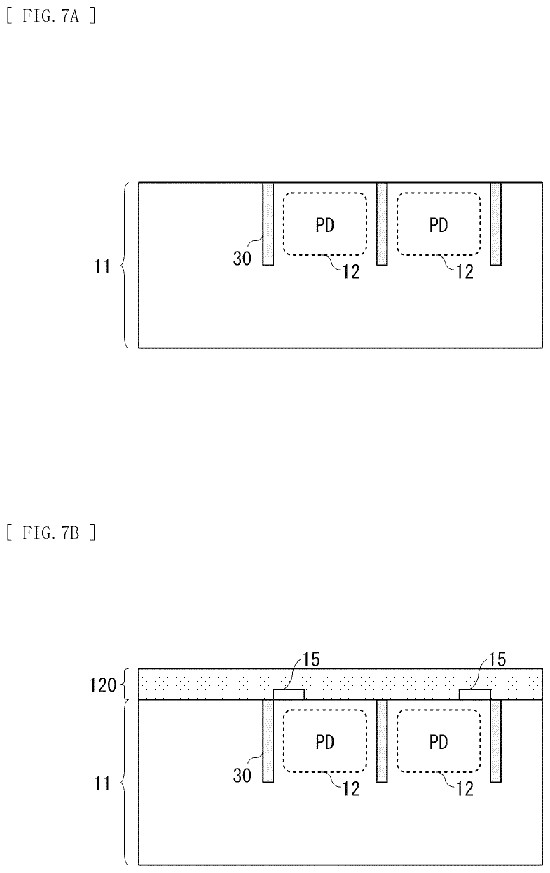

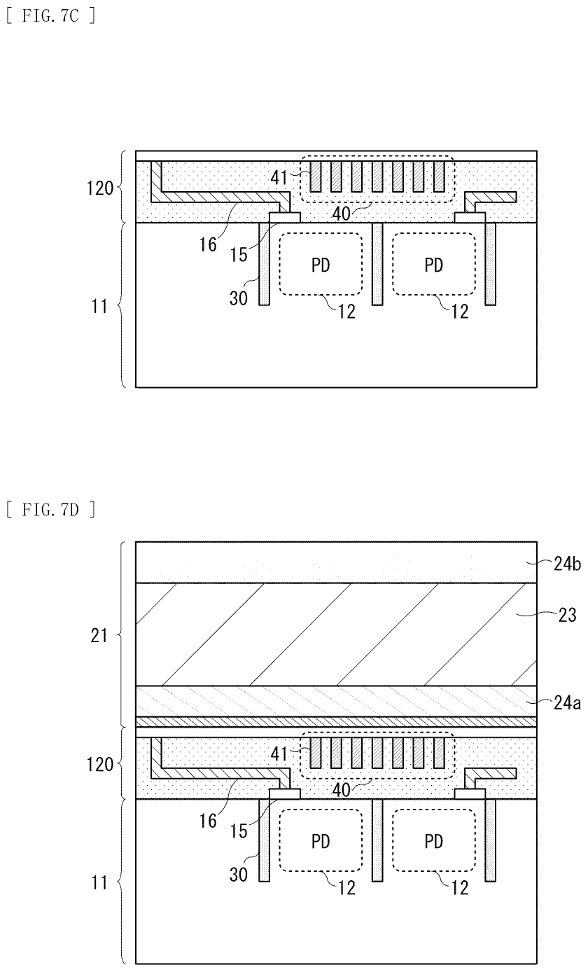

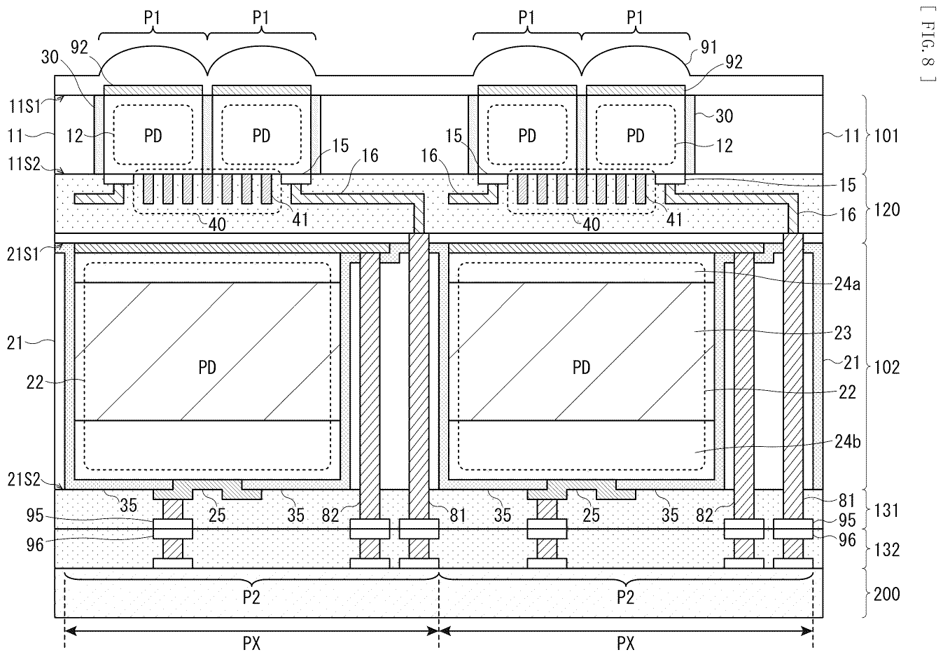

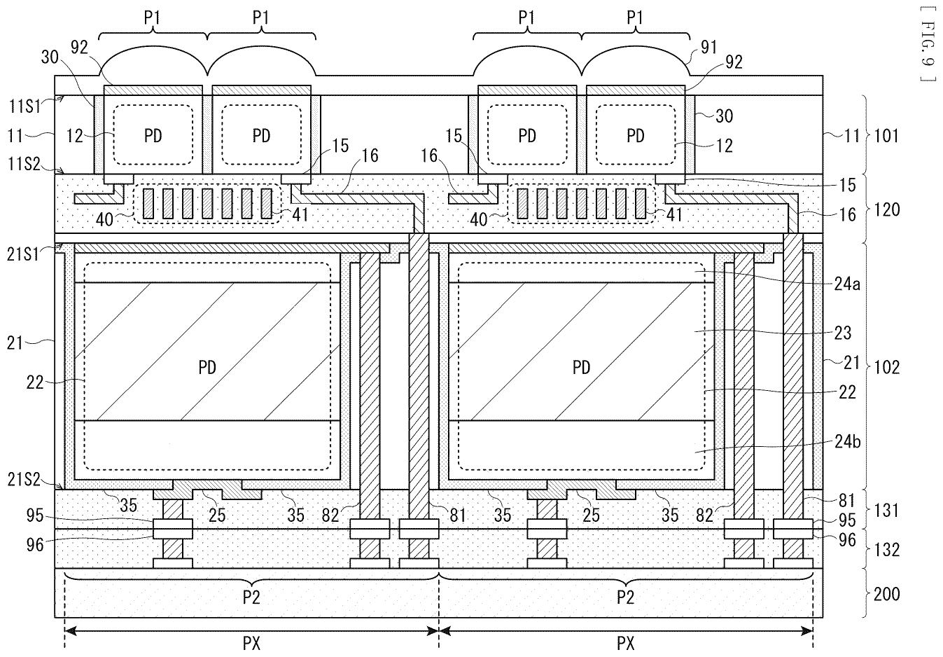

FIGS. 7A to 7D are diagrams describing an example of a manufacturing method of the imaging device according to the embodiment. First, as illustrated in FIG. 7A, the first photoelectric conversion sections 12, elements such as transistors, and the separators 30 are formed in the first semiconductor layer 11. Thereafter, as illustrated in FIG. 7B, the insulating layer 120 including the electrodes 15 is formed on the first semiconductor layer 11 in which the first photoelectric conversion sections 12 and the like are formed.

Thereafter, as illustrated in FIG. 7C, the light guide section 40 including the structures 41, the wirings 16, and the like are formed in the insulating layer 120. The structures 41 and the wirings 16 include, for example, polysilicon. For example, after a layer of polysilicon is formed, the polysilicon is selectively removed by lithography and etching, and an insulating film is embedded in the removed parts. This forms the light guide section 40 including the structures 41 in the insulating layer 120.

Alternatively, for example, the light guide section 40 including the plurality of structures 41 may be formed by selectively removing the insulating layer 120 by lithography and etching, and embedding polysilicon in the removed parts.

Thereafter, the first semiconductor layer 11 provided with the insulating layer 120 and the second semiconductor layer 21 including the semiconductor regions 23, 24a, and 24b are brought to oppose each other, and the first semiconductor layer 11 and the second semiconductor layer 21 are bonded to each other as illustrated in 7D. Thereafter, the electrodes 25, the through-electrodes 81 and 82, the filters 92, the lenses 91, and the like are formed. According to the above-described manufacturing method, it is possible to manufacture the imaging device 1 illustrated in FIG. 3 and the like. Note that the above-described manufacturing method is merely an example, and other manufacturing methods may be employed.

### Workings and Effects

The imaging device according to the present embodiment includes the first photoelectric conversion element (the first photoelectric conversion section 12) that photoelectrically converts light, the light guide member (the light guide section 40) including the plurality of first structures (the structures 41) and into which infrared light transmitted through the first photoelectric conversion element enters, and the second photoelectric conversion element (the second photoelectric conversion section 22) that photoelectrically converts infrared light that enters through the light guide member.

The imaging device 1 according to the present embodiment is provided with the light guide section 40 into which the infrared light transmitted through the first photoelectric conversion section 12 enters. It is therefore possible to guide the incident infrared light to the second photoelectric conversion section 22. This makes it possible to achieve an imaging device configured to efficiently receive light.

Next, modification examples of the present disclosure will be described. Hereinafter, components similar to those in the above-described embodiment are denoted by the same reference numerals, and description thereof will be omitted as appropriate.

### 2. Modification Examples

### 2-1. Modification Example 1

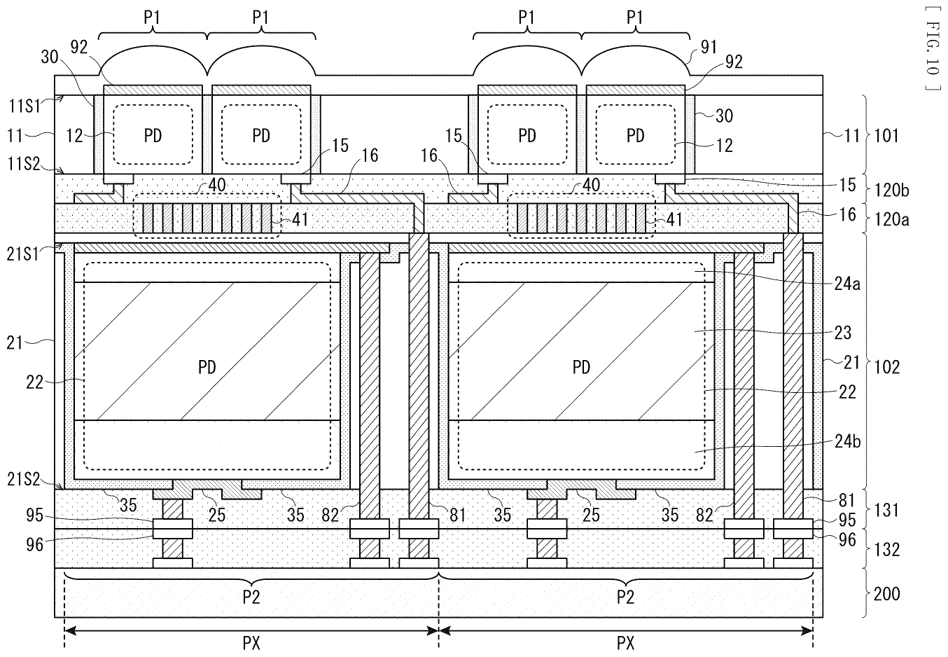

Although the arrangement example of the structures 41 has been described in the above-described embodiment, the arrangement of the structures 41 is not limited to the above-described example. FIG. 8 is a diagram illustrating an example of a sectional configuration of an imaging device according to Modification example 1 of the present disclosure. For example, as in the example illustrated in FIG. 8, the structures 41 of the light guide section 40 may be provided on the second surface 11S2 of the first semiconductor layer 11.

FIG. 9 is a diagram illustrating another example of a sectional configuration of an imaging device according to Modification example 1. As in the example illustrated in FIG. 9, the structures 41 of the light guide section 40 may be provided in a middle portion of the insulating layer 120 in the thickness direction. In the case of the present modification example also, it is possible to achieve effects similar to those of the above-described embodiment.

### 2-2. Modification Example 2

FIG. 10 is a diagram illustrating an example of a sectional configuration of an imaging device according to Modification example 2 of the present disclosure. The imaging device 1 may include an insulating layer having a two-layer structure between the first semiconductor layer 11 and the second semiconductor layer 21. In the example illustrated in FIG. 10, the imaging device 1 includes an insulating layer 120a and an insulating layer 120b. The insulating layer 120a and the insulating layer 120b are stacked on each other.

The insulating layer 120a has, for example, a refractive index different from that of the insulating layer 120b. The insulating film of the insulating layer 120a has, for example, a refractive index lower than the refractive index of the insulating film of the insulating layer 120b. The insulating film of the insulating layer 120a may include a material having a refractive index lower than the refractive index of the insulating film of the insulating layer 120b.

In the imaging device 1, for example, the light guide section 40 including the structures 41 may be provided in the insulating layer 120a having a relatively lower refractive index out of the insulating layer 120a and the insulating layer 120b. In this case, it is possible to relatively increase the difference in the refractive index between the structures 41 and the insulating film around the structures 41. This makes it possible to efficiently condense light by the light guide section 40 and to effectively suppress a decrease in sensitivity to the incident light.

### 2-3. Modification Example 3

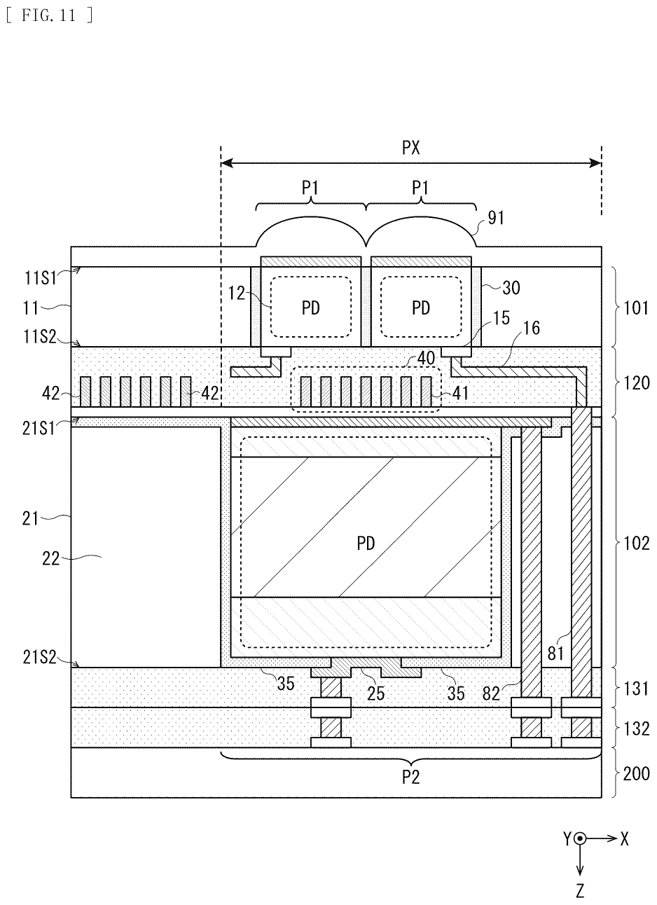

FIG. 11 is a diagram illustrating an example of a sectional configuration of an imaging device according to Modification example 3 of the present disclosure. As illustrated in FIG. 11, structures 42 may be provided in a region outside the pixel PX. The structures 42 are provided in the insulating layer 120 and are positioned outside the pixel PX in the insulating layer 120.

In the imaging device 1, with the structures 42 being provided, it is possible to improve the flatness of the insulating layer 120 (the wiring layer). This makes it possible to suppress occurrence of dishing when CMP processing is performed.

In the imaging device 1, for example, the plurality of structures 42 may be provided in a region outside the pixel section 100. The structures 42 may, for example, include the same material as the structures 41, such as polysilicon. Note that the structures 42 may include material such as silicon, polysilicon, amorphous silicon, or a metal compound, or may include other material.

The structures 42 may be provided on the first surface 21S1 of the second semiconductor layer 21, or may be provided on the second surface 11S2 of the first semiconductor layer 11. Alternatively, the structures 42 may be provided in a middle portion of the insulating layer 120 in the thickness direction.

### 2-4. Modification Example 4

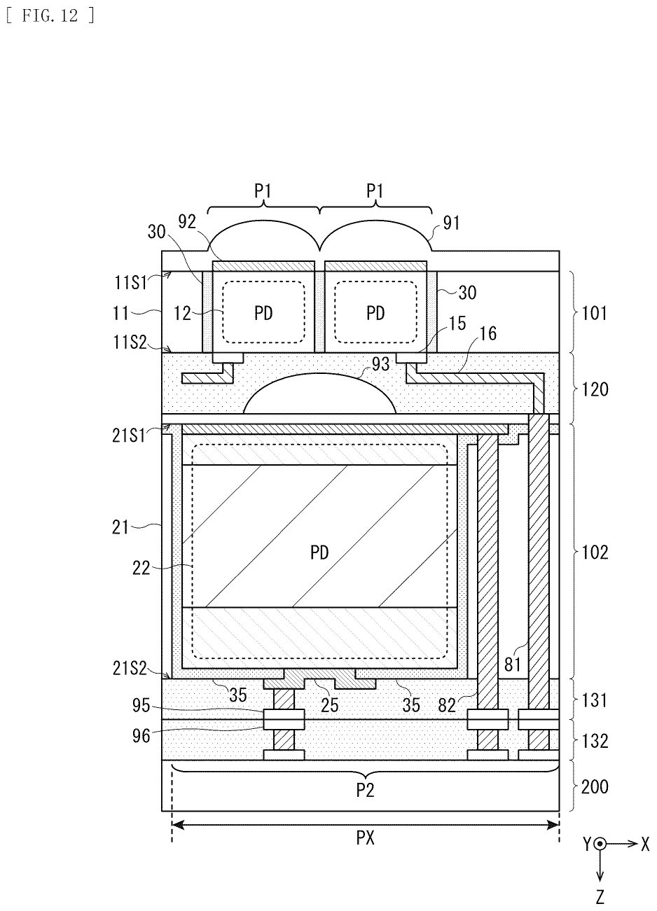

FIG. 12 is a diagram illustrating an example of a sectional configuration of an imaging device according to Modification example 4 of the present disclosure. As in the example illustrated in FIG. 12, a lens 93 may be provided between the first photoelectric conversion sections 12 and the second photoelectric conversion section 22. For example, the lens 93 is a convex lens and may include polysilicon. Note that the lens 93 may include other material.

### 2-5. Modification Example 5

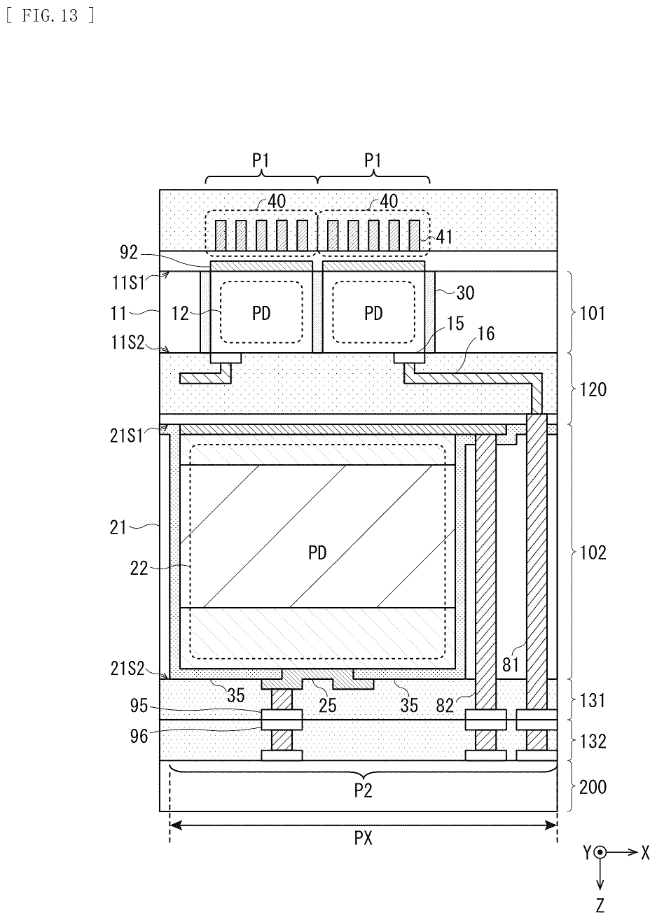

FIG. 13 is a diagram illustrating an example of a sectional configuration of an imaging device according to Modification example 5 of the present disclosure. As in the example illustrated in FIG. 13, the light guide section 40 including the structures 41 may be provided above the first photoelectric conversion section 12. The light guide section 40 is provided above the filter 92, for example, for each pixel P1 or for a plurality of pixels P1. For example, an insulating film such as an oxide film (e.g., a silicon oxide film) may be formed around the structures 41.

In the example illustrated in FIG. 13, the imaging device 1 has a configuration in which the light guide sections 40, the filters 92, the first photoelectric conversion sections 12, the insulating layer 120, the second photoelectric conversion sections 22, the wiring layer 131, the wiring layer 132, and the circuit layer 200 are stacked in the Z-axis direction.

The imaging device 1 according to the present modification example includes the light guide member (the light guide section 40) including the plurality of first structures (the structures 41), the first photoelectric conversion element (the first photoelectric conversion section 12) that photoelectrically converts light that enters through the light guide member, and the second photoelectric conversion element (the second photoelectric conversion section 22) that photoelectrically converts infrared light that enters through the first photoelectric conversion element. Therefore, the incident light from the subject is condensed by the light guide section 40, which is expected to suppress a decrease in sensitivity to the incident light.

### 2-6. Modification Example 6

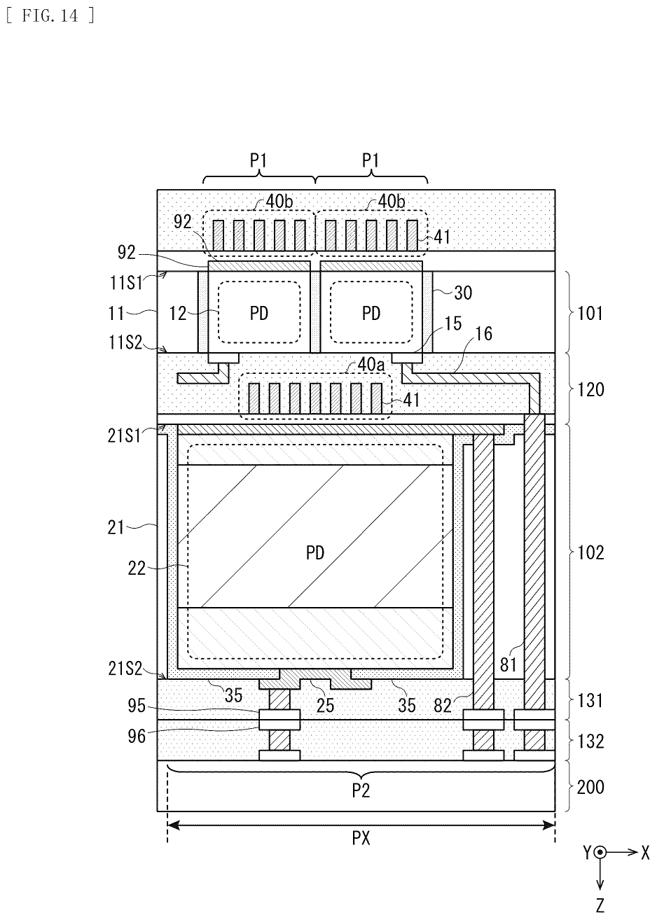

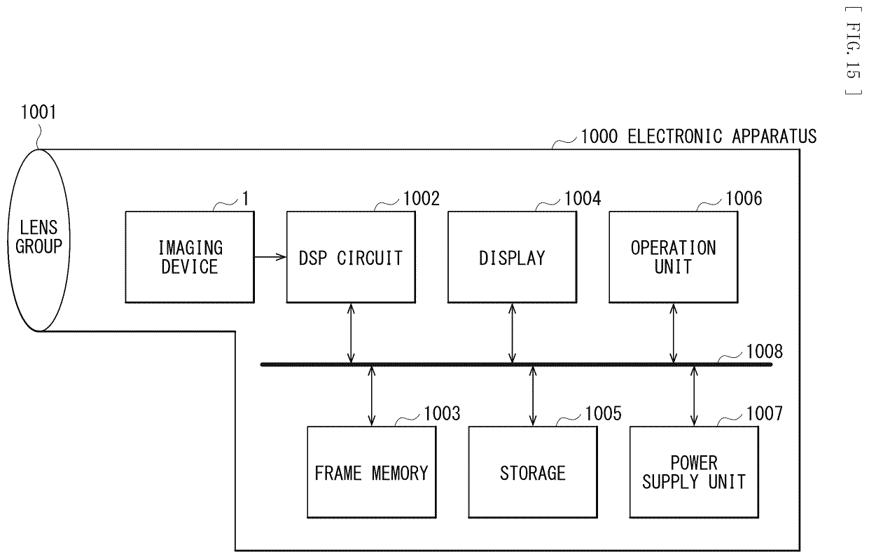

FIG. 14 is a diagram illustrating an example of a sectional configuration of an imaging device according to Modification example 6. As the example illustrated in FIG. 14, the imaging device 1 may include light guide sections 40a and light guide sections 40b. Each of the light guide sections 40a and the light guide sections 40b has a configuration similar to that of the light guide section 40 described above, and may include a plurality of structures 41. The imaging device 1 includes the light guide sections 40a provided between the first photoelectric conversion sections 12 and the second photoelectric conversion sections 22, and the light guide sections 40b provided above the first photoelectric conversion sections 12. In the case of the present modification example also, the effects similar to those of the above-described embodiment may be expected.

### 3. Application Example

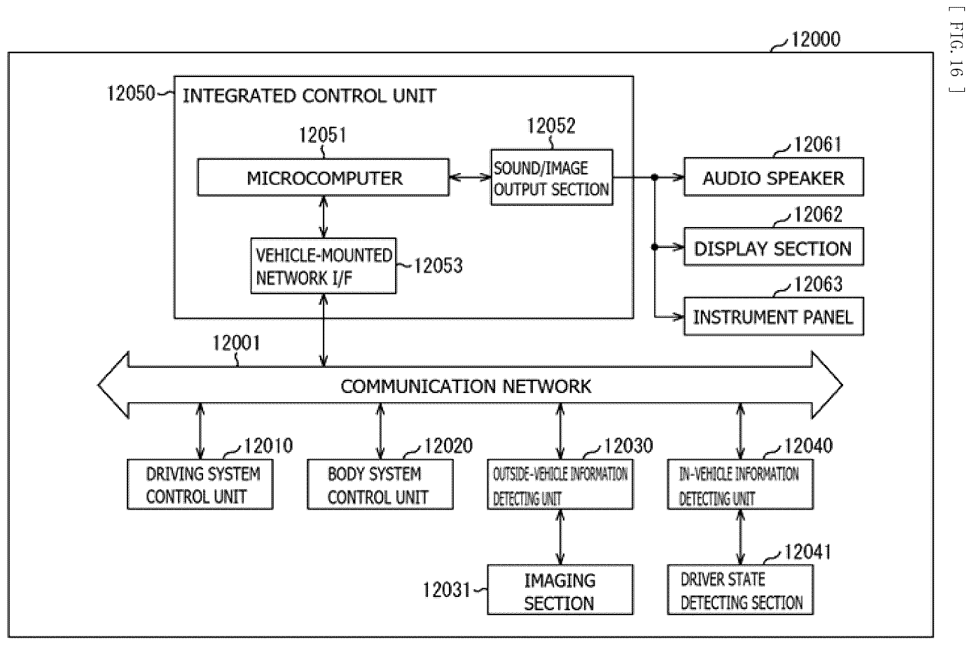

The imaging device 1 and the like are applicable to any type of electronic apparatuses having an imaging function including, for example, a camera system such as a digital still camera or a video camera, and a mobile phone having an imaging function. FIG. 15 illustrates a schematic configuration of an electronic apparatus 1000.

The electronic apparatus 1000 includes, for example, a lens group 1001, the imaging device 1, a DSP (Digital Signal Processor) circuit 1002, a frame memory 1003, a display 1004, a recorder 1005, an operation unit 1006, and a power supply unit 1007, which are coupled to each other via a bus line 1008.

The lens group 1001 takes in incident light (image light) from the subject and forms an image on an imaging surface of the imaging device 1. The imaging device 1 converts the amount of incident light formed as an image on the imaging surface by the lens group 1001 into electric signals on a pixel-unit basis, and supplies the electric signals to the DSP circuit 1002 as pixel signals.

The DSP circuit 1002 is a signal processing circuit that processes the signals supplied from the imaging device 1. The DSP circuit 1002 outputs the image data obtainable by processing the signals from the imaging device 1. The frame memory 1003 temporarily stores the image data processed by the DSP circuit 1002 in units of frames.

The display 1004 includes, for example, a panel display device such as a liquid crystal panel or an organic EL (Electro Luminescence) panel. The display 1004 records image data of a moving image or a still image captured by the imaging device 1 on a recording medium such as a semiconductor memory or a hard disk.

The operation unit 1006 outputs operation signals for various functions of the electronic apparatus 1000 in accordance with an operation performed by the user. The power supply unit 1007 appropriately supplies a variety of power sources to serve as respective operation power sources for the DSP circuit 1002, the frame memory 1003, the display 1004, the recorder 1005, and the operation unit 1006, to these targets of supply.

### Practical Application Example

### Example of Practical Application to Mobile Body

The technique according to the present disclosure (present technology) is applicable to various products. For example, the technique of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, a drone, a vessel, a robot, etc.

FIG. 16 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 16, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 16, an audio speaker 12061, a display section 12062, and an instrument panel 12063 are illustrated as the output device. The display section 12062 may, for example, include at least one of an on-board display and a head-up display.

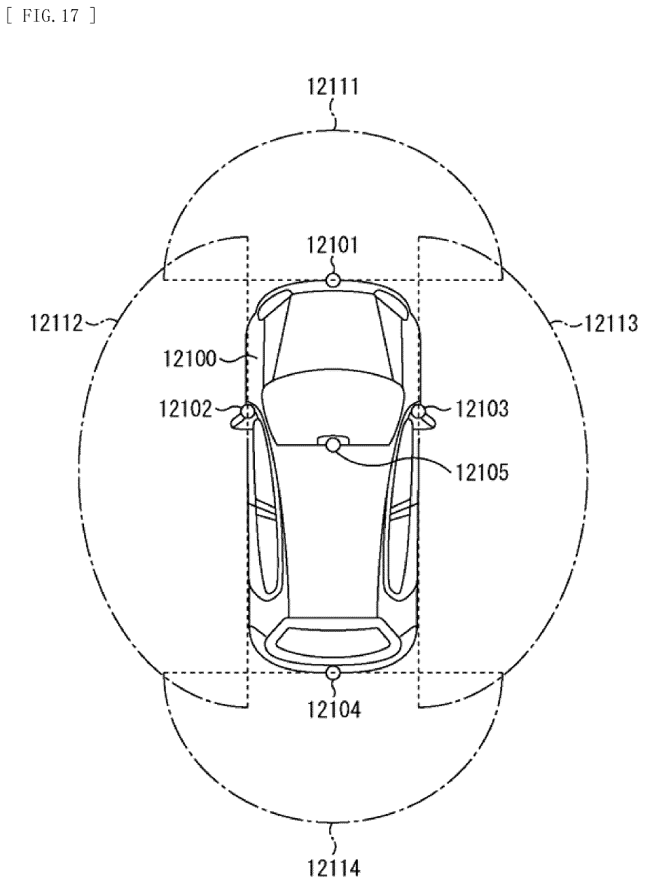

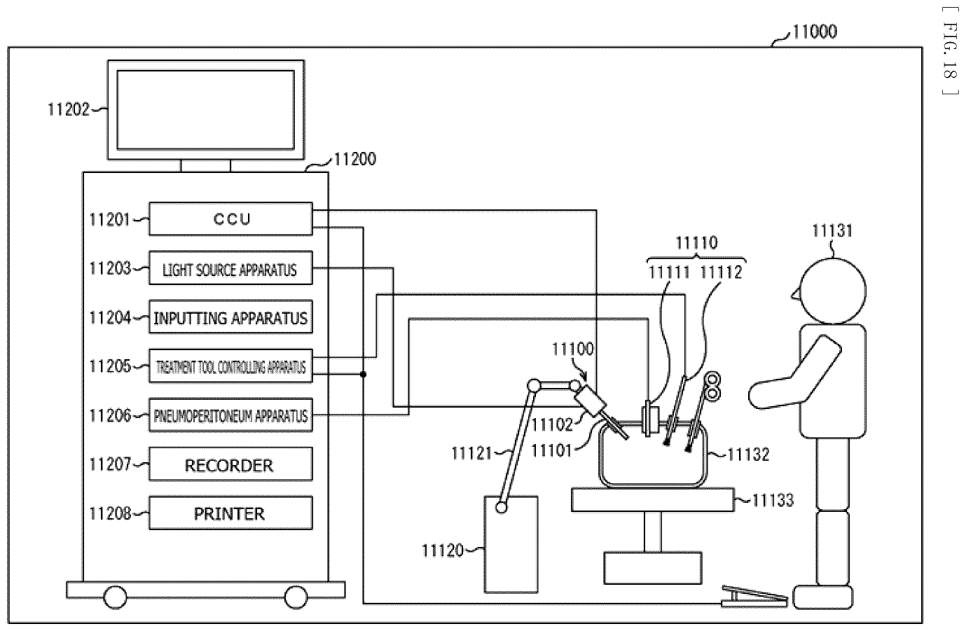

FIG. 17 is a diagram depicting an example of the installation position of the imaging section 12031.

In FIG. 17, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 17 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of one example of the mobile body control system, to which the technique according to the present disclosure may be applied. The technique according to the present disclosure may be applied to, for example, the imaging section 12031 out of the configuration described above. Specifically, for example, the imaging device 1 and the like are applicable to the imaging section 12031. The application of the technique according to the present disclosure to the imaging section 12031 allows for a high-definition captured image, thus making it possible to perform highly accurate control utilizing the captured image in the mobile body control system.

### Example of Practical Application to Endoscopic Surgery System

The technique according to the present disclosure (present technology) is applicable to various products. For example, the technique according to the present disclosure may be applied to an endoscopic surgery system.

FIG. 18 is a view depicting an example of a schematic configuration of an endoscopic surgery system to which the technology according to an embodiment of the present disclosure (present technology) can be applied.

In FIG. 18, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

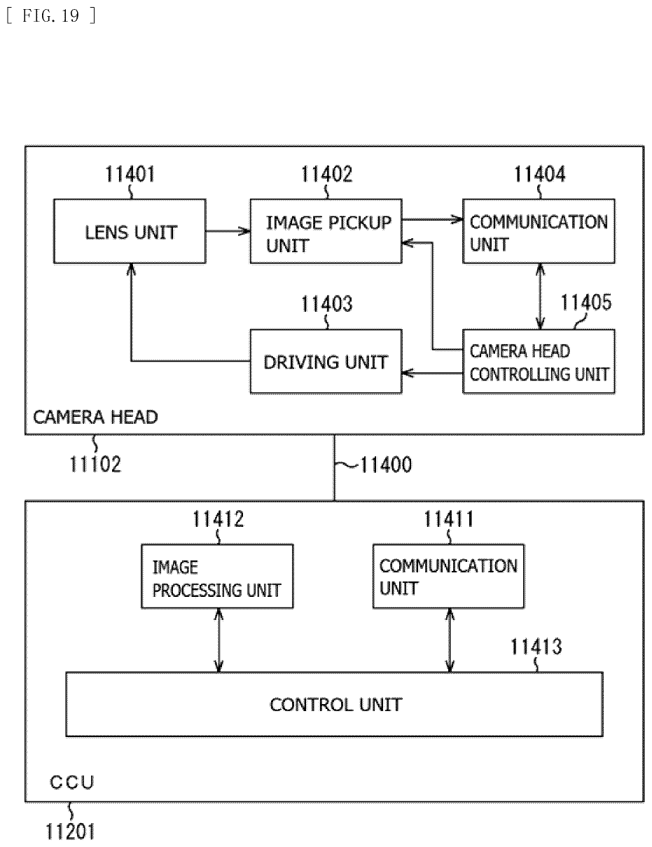

FIG. 19 is a block diagram depicting an example of a functional configuration of the camera head 11102 and the CCU 11201 depicted in FIG. 18.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technique according to the present disclosure is applicable. The technique according to the present disclosure is suitably applicable to, for example, the image pickup unit 11402 provided on the camera head 11102 of the endoscope 11100 of the configurations described above. Applying the technique according to the present disclosure to the image pickup unit 11402 makes it possible to provide a high-definition endoscope 11100.

Although the present disclosure has been described with reference to the embodiments, the modification examples, the application example, and the practical application example, the present technology is not limited to the above-described embodiment and the like, and various modifications are possible. For example, although the above-described modification examples have been described as the modification examples of the above-described embodiment, the configurations of the modification examples may be combined as appropriate.

The imaging device (photodetector) according to one embodiment of the present disclosure includes the first photoelectric conversion element that photoelectrically converts light, the light guide member that includes the plurality of first structures and into which infrared light transmitted through the first photoelectric conversion element enters, and the second photoelectric conversion element that photoelectrically converts infrared light that enters through the light guide member. This makes it possible to achieve an imaging device configured to efficiently receive light.

The imaging device according to one embodiment of the present disclosure includes the light guide member including the plurality of first structures, the first photoelectric conversion element that photoelectrically converts light that enters through the light guide member, and the second photoelectric conversion element that photoelectrically converts infrared light that enters through the first photoelectric conversion element. This makes it possible to achieve an imaging device configured to efficiently receive light.

It is to be noted that effects described herein are merely examples, and the description thereof is non-limiting, and other effects may be provided. Further, the present disclosure may have the following configuration.
(1)

An imaging device including:
a first photoelectric conversion element that photoelectrically converts light;
a light guide member including a plurality of first structures and into which infrared light transmitted through the first photoelectric conversion element enters; and
a second photoelectric conversion element that photoelectrically converts the infrared light that enters through the light guide member.
(2)

The imaging device according to (1), in which the first structure has a size smaller than or equal to a wavelength range of the infrared light.
(3)

The imaging device according to (1) or (2), in which the second photoelectric conversion element includes a compound semiconductor material.
(4)

The imaging device according to any one of (1) to (3), further including
a first insulating layer provided between the first photoelectric conversion element and the second photoelectric conversion element, in which
the light guide member is provided in the first insulating layer.
(5)

The imaging device according to (4), in which the first structure has a refractive index higher than a refractive index of the first insulating layer.
(6)

The imaging device according to (4) or (5), further including
a wiring provided in the first insulating layer, in which
the first structure includes a same material as the wiring.
(7)

The imaging device according to (6), in which the first structure and the wiring each include polysilicon.
(8)

The imaging device according to any one of (4) to (7), in which the first insulating layer includes a wiring layer provided between the first photoelectric conversion element and the second photoelectric conversion element.
(9)

The imaging device according to any one of (4) to (8), in which
the first insulating layer includes a wiring layer including a wiring provided for the first photoelectric conversion element, and
the first structure is provided around the wiring.
(10)

The imaging device according to (9), in which the first structure includes a same material as the wiring.
(11)

The imaging device according to (9) or (10), in which the first structure and the wiring each include polysilicon.
(12)

The imaging device according to any one of (4) to (11), further including:
a pixel including the first photoelectric conversion element and the second photoelectric conversion element; and
a second structure provided in the first insulating layer and positioned outside the pixel.
(13)

The imaging device according to any one of (1) to (12), further including:
a first insulating layer provided between the first photoelectric conversion element and the second photoelectric conversion element; and
a second insulating layer stacked on the first insulating layer, between the first photoelectric conversion element and the second photoelectric conversion element, in which
the first insulating layer has a refractive index lower than a refractive index of the second insulating layer, and
the light guide member is provided in the first insulating layer.
(14)

The imaging device according to any one of (1) to (13), in which the plurality of first structures is provided side by side in a first direction and a second direction intersecting the first direction, in a plan view.
(15)

The imaging device according to any one of (1) to (14), in which the plurality of first structures adjacent to each other is provided with a spacing less than or equal to a wavelength range of the infrared light.
(16)

The imaging device according to any one of (1) to (15), in which the first photoelectric conversion element photoelectrically converts visible light.
(17)

The imaging device according to any one of (1) to (16), in which the first structure has a columnar shape.
(18)

An imaging device including:
a light guide member including a plurality of first structures;
   a first photoelectric conversion element that photoelectrically converts light that enters through the light guide member; and
   a second photoelectric conversion element that photoelectrically converts infrared light that enters through the first photoelectric conversion element.
(19)

The imaging device according to (18), in which the first structure has a size smaller than or equal to a wavelength range of the infrared light or a size smaller than or equal to a wavelength range of visible light.
(20)

An electronic apparatus including an imaging device, the imaging device including:
a first photoelectric conversion element that photoelectrically converts light;
a light guide member including a plurality of first structures and into which infrared light transmitted through the first photoelectric conversion element enters; and
a second photoelectric conversion element that photoelectrically converts the infrared light that enters through the light guide member.
(21)

An electronic apparatus including an imaging device, the imaging device including:
a light guide member including a plurality of first structures;
   a first photoelectric conversion element that photoelectrically converts light that enters through the light guide member; and
   a second photoelectric conversion element that photoelectrically converts infrared light that enters through the first photoelectric conversion element.

This application claims the benefit of Japanese Priority Patent Application JP2023-074722 filed with the Japan Patent Office on Apr. 28, 2023, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. An imaging device comprising:
a first photoelectric conversion element that photoelectrically converts light;
a light guide member including a plurality of first structures and into which infrared light transmitted through the first photoelectric conversion element enters; and
a second photoelectric conversion element that photoelectrically converts the infrared light that enters through the light guide member.

2. The imaging device according to claim 1, wherein the first structure has a size smaller than or equal to a wavelength range of the infrared light.

3. The imaging device according to claim 1, wherein the second photoelectric conversion element includes a compound semiconductor material.

4. The imaging device according to claim 1, further comprising
a first insulating layer provided between the first photoelectric conversion element and the second photoelectric conversion element, wherein
the light guide member is provided in the first insulating layer.

5. The imaging device according to claim 4, wherein the first structure has a refractive index higher than a refractive index of the first insulating layer.

6. The imaging device according to claim 4, further comprising
a wiring provided in the first insulating layer, wherein
the first structure includes a same material as the wiring.

7. The imaging device according to claim 6, wherein the first structure and the wiring each include polysilicon.

8. The imaging device according to claim 4, wherein the first insulating layer comprises a wiring layer provided between the first photoelectric conversion element and the second photoelectric conversion element.

9. The imaging device according to claim 4, wherein
the first insulating layer comprises a wiring layer including a wiring provided for the first photoelectric conversion element, and
the first structure is provided around the wiring.

10. The imaging device according to claim 9, wherein the first structure includes a same material as the wiring.

11. The imaging device according to claim 9, wherein the first structure and the wiring each include polysilicon.

12. The imaging device according to claim 4, further comprising:
a pixel including the first photoelectric conversion element and the second photoelectric conversion element; and
a second structure provided in the first insulating layer and positioned outside the pixel.

13. The imaging device according to claim 1, further comprising:
a first insulating layer provided between the first photoelectric conversion element and the second photoelectric conversion element; and
a second insulating layer stacked on the first insulating layer, between the first photoelectric conversion element and the second photoelectric conversion element, wherein
the first insulating layer has a refractive index lower than a refractive index of the second insulating layer, and
the light guide member is provided in the first insulating layer.

14. The imaging device according to claim 1, wherein the plurality of first structures is provided side by side in a first direction and a second direction intersecting the first direction, in a plan view.

15. The imaging device according to claim 1, wherein the plurality of first structures adjacent to each other is provided with a spacing less than or equal to a wavelength range of the infrared light.

16. The imaging device according to claim 1, wherein the first photoelectric conversion element photoelectrically converts visible light.

17. The imaging device according to claim 1, wherein the first structure has a columnar shape.

18. An imaging device comprising:
a light guide member including a plurality of first structures;
a first photoelectric conversion element that photoelectrically converts light that enters through the light guide member; and
a second photoelectric conversion element that photoelectrically converts infrared light that enters through the first photoelectric conversion element.

19. The imaging device according to claim 18, wherein the first structure has a size smaller than or equal to a wavelength range of the infrared light or a size smaller than or equal to a wavelength range of visible light.

20. An electronic apparatus including an imaging device, the imaging device comprising:
a first photoelectric conversion element that photoelectrically converts light;
a light guide member including a plurality of first structures and into which infrared light transmitted through the first photoelectric conversion element enters; and
a second photoelectric conversion element that photoelectrically converts the infrared light that enters through the light guide member.
